(19) United States
(12) Patent Application Publication
(10) Pub. No.: US 2025/0300608 A1
(43) Pub. Date: Sep. 25, 2025

(54) AMPLIFIER CIRCUIT AND METHOD FOR AMPLIFYING AN AUDIO SIGNAL

(71) Applicant: POWERSOFT S.P.A., Scandicci (IT)

(72) Inventors: Claudio LASTRUCCI, Lastra A Signa (IT); Leonardo Bracciotti, Montespertoli (IT)

(21) Appl. No.: 19/079,021

(22) Filed: Mar. 13, 2025

(30) Foreign Application Priority Data
Mar. 22, 2024 (IT) 102024000006415

(51) Int. Cl. H03F 3/187; H03F 3/45

(52) U.S. Cl. CPC H03F 3/187; H03F 3/45475; H03F 2200/03

(57) ABSTRACT

An amplifier circuit (1) for amplifying an audio signal, includes: an input stage (I) for receiving a first input signal representing the audio signal; a transformer (T) including a primary winding (L₁) and a secondary winding (L₂), defining a first terminal, a second terminal and a middle terminal; a differential amplifier (U), having a first input (U₊), connected to the first terminal of the secondary winding (L₂); a second input (U₋), connected to the middle terminal of the secondary winding (L₂), and an output (Uₒᵤₜ), connected to the second terminal of the secondary winding (L₂); an additional transformer (T′) including an additional primary winding (L₁′) and secondary winding (L₂′), defining a first terminal, a second terminal and a middle terminal; an additional differential amplifier (U′), having a first input (U₊′), connected to the first terminal of the additional secondary winding (L₂′), a second input (U₊′) connected to the middle terminal of the additional secondary winding (L₂′) and an output (Uₒᵤₜ′) connected to the second terminal of the additional secondary winding (L₂′); an output circuit (O) for receiving as input the output signals from the differential amplifier (U) and from the additional differential amplifier (U′) to generate a differential output signal (Vₒᵤₜ).

### FIELD OF THE INVENTION

This invention relates to an amplifier circuit and to a method for amplifying an audio signal.

### BACKGROUND OF THE INVENTION

In the field of audio signal amplifiers, there is a need to minimize the noise and distortion associated with the signal.

Traditionally, the prior art teaches the use of solutions which involve galvanically isolating an input stage of the signal from the amplifying stage of the signal, so as to make the amplifying circuit more robust against external signal noise.

Of the solutions which involve galvanic isolation, one example consists in first digitizing the input signal, decoupling it via an optical transmission system (in particular, a photocoupler) and then reconverting the digital signal into an analog signal to feed it as input to a loudspeaker. Prior to decoupling, this solution uses active electronic components (in particular, operational amplifiers and/or analog-to-digital converters) which need a dedicated electrical power supply. This solution therefore has the disadvantage of necessitating additional isolation of the powered section.

Another solution involves the use of a transformer to galvanically isolate the input stage from the amplifying stage. The magnetic field induced in the transformer is not linear, however, and this produces signal distortions through the transformer. Patent documents U.S. Pat. Nos. 4,567,443 and 3,828,269 describe examples for reducing the distortions generated by the transformer. In particular, in document U.S. Pat. No. 4,567,443, the output signal from the differential amplifier is fed to a secondary winding of an additional transformer which is electrically connected to the first transformer.

In document U.S. Pat. No. 3,828,269, on the other hand, the output signal from the differential amplifier is fed to one end of the secondary winding of the transformer itself. This solution, however, tends to increase the sensitivity of the circuit to external nose, which means the transformer must be shielded using noble materials, making the system very expensive. Also patent documents US2020/127620A1 and U.S. Pat. No. 2,710,312A describe examples of amplifier circuits; however, neither those documents are able to satisfy the market's needs.

### BRIEF SUMMARY OF THE INVENTION

This disclosure has for an aim to provide an amplifier circuit and a method for amplifying an audio signal to overcome the above-mentioned disadvantages of the prior art. In particular, the aim of this disclosure is to provide an amplifier circuit and a method for amplifying an audio signal capable of generating an output signal which is free of noise, free of distortion and galvanically isolated.

Another aim of this invention is to propose an amplifier circuit which is capable of suppressing common mode noise. This invention also allows extending the low-frequency response using small transformers.

In addition, this invention provides an amplifier circuit and a method for amplifying an audio signal which can reduce the transformer distortion without using additional shielding.

These aims are fully achieved by the amplifier circuit and method for amplifying an audio signal of this invention, as characterized in the appended claims.

In particular, the amplifier circuit for amplifying an audio signal comprises an input stage.

The input stage is responsible for receiving a signal representing the audio signal to be amplified.

The input stage comprises a first pin (which defines a first input node) and a second pin (which defines a second input node). Hereinafter, the terms first input node and second input mode are used as synonyms for the terms first pin and second pin, respectively.

The first input node is responsible for receiving a first input signal representing an audio signal. The second input node is responsible for receiving a second input signal representing the audio signal. Preferably, the second input signal is 180° out of phase with the first input signal.

That way, the first input signal and the second input signal constitute a balanced signal.

The amplifier circuit comprises a transformer. The transformer includes a primary winding and a secondary winding. The secondary winding defines (or includes) a first terminal and a second terminal. Preferably, the secondary winding defines (or includes) a middle terminal. The first terminal, the second terminal and the middle terminal may define a first secondary winding and a second secondary winding. To make the first secondary winding and the second secondary winding, two approaches are possible. In a first approach, the first secondary winding and the second secondary winding are (constitute) two distinct windings; in the first approach, the first secondary winding is between the first terminal and the middle terminal, and the second secondary winding is between the middle terminal and the second terminal. In a second approach, there is a single winding between the first terminal and the second terminal (thus, the secondary winding is a single winding) and the middle terminal is defined by a central socket of the secondary winding (that is, of the single winding). Thus, in the second approach, the central socket (that is, the middle terminal) divides the secondary winding into a first secondary winding and a second secondary winding. The first terminal, the second terminal and the middle terminal respectively define a first end, a second end and a central socket. Preferably, the secondary winding defines a central socket. In particular, the central socket is located between the first end and the second end. The central socket may divide the secondary winding into a first secondary winding and a second secondary winding so as to form a double secondary winding.

According to an aspect, the secondary winding may include a first secondary winding and a second secondary winding, where the first secondary winding and the second secondary winding are respective, distinct windings. In this case, the central socket may not be present.

The amplifier circuit comprises a differential amplifier. The differential amplifier includes a first input, a second input and an output. In particular, the first input is electrically connected to the first terminal of the secondary winding by a first connecting branch. The second input is electrically connected to the middle terminal of the secondary winding by a second connecting branch. The output is connected to the second terminal of the secondary winding.

The amplifier circuit comprises an additional transformer. The additional transformer includes an additional primary winding and an additional secondary winding. The additional secondary winding defines (or includes) a first terminal and a second terminal.

Preferably, the additional secondary winding defines (or includes) a middle terminal. The first terminal, the second terminal and the middle terminal may define an additional first secondary winding and an additional second secondary winding. To make the additional first secondary winding and the additional second secondary winding, two approaches are possible. In a first approach, the additional first secondary winding and the additional second secondary winding are (constitute) two distinct windings; in the first approach, the additional first secondary winding is between the first terminal and the middle terminal, and the additional second secondary winding is between the middle terminal and the second terminal. In a second approach, there is an additional single winding between the first terminal and the second terminal (thus, the additional secondary winding is a single winding) and the middle terminal is defined by a central socket of the additional secondary winding (that is, of the single winding). Thus, in the second approach, the central socket (that is, the middle terminal) divides the additional secondary winding into an additional first secondary winding and an additional second secondary winding. The first terminal, the second terminal and the middle terminal respectively define a first end, a second end and a central socket. The additional secondary winding defines a first end and a second end. Preferably, the additional secondary winding defines a central socket. In particular, the central socket is located between the first end and the second end of the additional secondary winding. The central socket may divide the additional secondary winding into an additional first secondary winding and an additional second secondary winding so as to form an additional double secondary winding.

According to an aspect, the secondary winding may include a first secondary winding and a second secondary winding, where the first secondary winding and the second secondary winding are respective, distinct windings. In this case, the central socket may not be present.

In particular, the primary winding and the additional primary winding are electrically connected (in particular, electrically connected in series) across the first input node and the second input node.

The amplifier circuit comprises an additional differential amplifier. The additional differential amplifier includes a first input, a second input and an output. In particular, the first input is electrically connected to the first terminal of the additional secondary winding of the additional transformer by a first connecting branch. The second input is electrically connected to the middle terminal of the additional secondary winding by a second connecting branch. The output is connected to the second terminal of the additional secondary winding.

Therefore, the differential amplifier and the additional differential amplifier each amplify the voltage difference present across its own inputs, and the output signal powers, that is, is injected into, the second end (that is, the second terminal) of the respective transformer; that way, the voltage difference is cancelled, bringing the induction of the respective transformer core to near zero.

The amplifier circuit comprises an output circuit for receiving as input the output signals from the differential amplifier and from the additional differential amplifier to generate a differential output signal.

In particular, to generate the differential output signal, the output circuit may comprise a differential output amplifier; the differential output amplifier is responsible for receiving as input the output signals from the differential amplifier and from the additional differential amplifier so as to generate a differential output signal. The differential output signal may be generated in other ways, however, such as, for example, with an analog circuit or with a digital circuit (for example, the output signal from the differential amplifier and from the additional differential amplifier might be digitized and processed to obtain the differential output signal).

The output signal from the differential amplifier and the output signal from the additional differential amplifier may be 180° out of phase with each other. The output circuit may be responsible for generating a differential output signal proportional to the difference between the output signal from the differential amplifier and the output signal from the additional differential amplifier. That way, the output signal from the differential amplifier is further cleaned of common mode noise between the output signal from the amplifier and the output signal from the additional amplifier.

Thus, the amplifier circuit has the advantage of suppressing the noise caused by the stray capacitance produced between windings of the transformers.

In an example, the primary winding of the transformer and the additional primary winding of the additional transformer are configured to generate a magnetic flux and an opposite, additional magnetic flux. In other words, the primary winding and the additional primary winding are connected in such a way as to have discordant polarity. Therefore, the magnetic flux generated by the primary winding of the transformer and the magnetic flux generated by the additional primary winding of the additional transformer cancel each other out.

Preferably, for both the differential amplifier and the additional differential amplifier, the first input is a non-inverting input and the second input is an inverting input.

For both the differential amplifier and the additional differential amplifier, the first secondary winding and the second secondary winding have concordant polarity. For both the transformer and the additional transformer, the primary winding and the secondary winding may have concordant polarity, that is, additive polarity.

In an example, the transformer and the additional transformer are identical, placed side by side and oriented in the same way, so that an external magnetic flux generates the same current in the transformer and in the additional transformer. In other words, the turns of the windings of the transformer and of the additional transformer must be wound along axes which are parallel to each other, that is to say, the turns of the windings of the transformer and of the additional transformer must be wound on parallel stretches of their cores.

Preferably, the transformer and the additional transformer are located relative to each other at a distance such that an external magnetic flux generates the same current in the transformer and in the additional transformer.

Thus, the transformer and the additional transformer are geometrically arranged relative to each other in such a way that the noise caused by external magnetic fields is suppressed. In other words, the purpose of such an arrangement is that the noise caused by external sources is made common to both of the transformers and removed by the electronic circuit, which is essentially sensitive to signals of differential type.

It is noted that, generally speaking, because the differential amplifier is an active component which draws on an external power source to produce a voltage and current (power) gain, when it acts on the transformer, it makes the transformer more sensitive to external electromagnetic fields; using a double isolation system (a first system comprising the transformer and the amplifier and a second system comprising the additional transformer and the additional amplifier) has the advantage of reducing the noise caused by external electromagnetic fields without having to use expensive shielding systems. As regards the secondary winding and the additional secondary winding, the inductance of the first secondary winding and the inductance of the second secondary winding may have the same value or different values. Preferably, the inductance of the first secondary winding is greater than the inductance of the second secondary winding. More preferably, the inductance of the first secondary winding is 100 times greater than the inductance of the second secondary winding. The asymmetry in the inductance values between the first secondary winding and the second secondary winding has the advantage of improving the signal-to-noise ratio, in that it is possible to reduce the impedance of the active cancellation circuit to lower values, reducing the overall thermal noise of the components in play.

In an example, for both the differential amplifier and the additional differential amplifier, the output is connected to the second input by a first impedance.

For both the differential amplifier and the additional differential amplifier, the second connecting branch includes a second impedance, so that the second input can be connected to the middle terminal of the respective secondary winding through the second impedance. For both the differential amplifier and the additional differential amplifier, the output may be connected to the second terminal of the respective secondary winding through a third impedance.

Preferably, the amplifier circuit comprises a ground connection between the second impedance and the middle terminal for both the differential amplifier and the additional differential amplifier.

In an example, the first and/or the second and/or the third impedance comprise a resistive component. The first and/or the second and/or the third impedance may comprise a capacitive component.

Preferably, the transformer and the additional transformer are identical. Preferably, the transformer comprises a core and the additional transformer comprises an additional core which is distinct from the core of the transformer.

In an example, the output circuit comprises a differential output amplifier to generate the balanced differential output signal.

This disclosure also provides a method for amplifying an audio signal. The method comprises a step of receiving an input signal representing an audio signal. Preferably, the method comprises a step of receiving a first input signal representing an audio signal at a first input node of an input stage. Preferably, the method comprises a step of receiving, at a second input node of the input stage, a second input signal, representing the audio signal and being 180° out of phase with the first input signal.

The method comprises a step of providing a transformer including a primary winding and a secondary winding. The secondary winding defines (or includes) a first terminal and a second terminal. Preferably, the secondary winding defines (or includes) a middle terminal. The first terminal, the second terminal and the middle terminal may define a first secondary winding and a second secondary winding. The first terminal, the second terminal and the middle terminal respectively define a first end, a second end and a central socket.

The method comprises a step of providing a differential amplifier, having a first input which is electrically connected to the first terminal of the secondary winding by a first connecting branch, a second input which is electrically connected the middle terminal of the secondary winding by a second connecting branch, and an output which is connected to the second terminal of the secondary winding.

The method comprises a step of providing an additional transformer which includes an additional primary winding and an additional secondary winding.

The secondary winding defines (or includes) a first terminal and a second terminal.

Preferably, the additional secondary winding defines (or includes) a middle terminal. The first terminal, the second terminal and the middle terminal may define an additional first secondary winding and an additional second secondary winding. The first terminal, the second terminal and the middle terminal respectively define a first end, a second end and a central socket.

Preferably, the primary winding and the additional primary winding are electrically connected in series across the first input node and the second input node.

The method comprises a step of providing an additional differential amplifier, having a first input which is electrically connected to the first terminal of the additional secondary winding by a first connecting branch, a second input which is electrically connected to the middle terminal of the additional secondary winding by a second connecting branch, and an output which is connected to the second terminal of the additional secondary winding of the additional transformer.

Preferably, the method comprises a step of generating a balanced differential output signal from the output signals from the differential amplifier and from the additional differential amplifier to make the balanced differential output signal available to an output stage.

In an example, the method comprises a step, via the primary winding of the transformer, of generating a magnetic flux, and via the additional primary winding of the additional transformer, of generating an additional magnetic flux, opposite of the magnetic flux.

For both the differential amplifier and the additional differential amplifier, the output may be connected to the second input of the respective differential amplifier through the first impedance. For both the differential amplifier and the additional differential amplifier, the second connecting branch includes a second impedance, so that the second input can be connected to the central socket of the respective secondary winding through the second impedance. Preferably, the second impedance is connected to the middle terminal by a ground connection. For both the differential amplifier and the additional differential amplifier, the output may be connected to the second terminal of the respective secondary winding through a third impedance.

In an example, the method comprises a step of providing a differential output amplifier at an output circuit to generate the balanced differential output signal.

In the embodiment of the method, the transformer and the additional transformer, the differential amplifier and the additional differential amplifier may be made according to one or more of the features described in this disclosure.

This disclosure also provides an audio amplifier.

The audio amplifier comprises an amplifier circuit made according to one or more aspects of this disclosure.

The audio amplifier comprises a power amplifier. The amplifier circuit may be located upstream or downstream of the power amplifier (relative to the travel direction of the signal inside the audio amplifier); in other words, the amplifier circuit may be configured to (directly or indirectly) feed an output signal from the amplifier circuit (that is, a balanced differential output signal) to the power amplifier, or to receive an (amplified) output signal from the power amplifier.

When it is located upstream of the power amplifier, the amplifier circuit constitutes or defines a system for the galvanic isolation of the input signal to the audio amplifier. Such a circuit, therefore, may be used to increase the common-mode rejection ratio to shield signal lines, to reduce or eliminate ground loops caused by potential differences between two parts of a circuit or to shield the circuit from external electromagnetic fields.

Such an amplifier circuit may also be used to isolate electrically conductive, user-accessible components from the mains so as to ensure electrical safety.

For example, the audio amplifier may be configured to amplify an input signal to a loudspeaker (that is, to feed an amplified signal to a loudspeaker). The audio amplifier, in particular the amplifier circuit of the audio amplifier, may be configured to receive a mains power supply signal through an input connector (which is accessible to a user). In particular, the power amplifier of the audio amplifier may be configured to feed an amplified signal to a loudspeaker. Thus, the amplifier circuit is located upstream of the power amplifier. Used this way, the amplifier circuit is configured to galvanically isolate the input connector from the mains. It is noted that the system made up of the input connector, the audio amplifier and the loudspeaker constitutes an active diffuser.

When it is located downstream of the power amplifier, the amplifier circuit constitutes or defines a system for the galvanic isolation of the output signal from the power amplifier.

Such a circuit may be used to perform measurements of current and/or voltage of the output signal from the power amplifier.

For example, the audio amplifier may be configured to perform a measurement of current and/or voltage of the signal output from the power amplifier. The amplifier circuit of the audio amplifier may be configured to receive an output signal from the power amplifier.

The amplifier circuit of the audio amplifier may be configured to generate an output signal representing a value of a current and/or voltage output by the power amplifier. The audio amplifier may comprise a shunt resistor located at the output of the power amplifier (that is, the shunt resistor is configured to receive the output signal from the power amplifier).

The amplifier circuit may be connected to the ends of the shunt resistor.

Thus, when the amplifier circuit is located this way, its purpose is to reduce the common-mode rejection ratio, hence to perform a more accurate measurement at the ends of the shunt resistor.

According to an aspect of this disclosure, the audio amplifier comprises a first stage, including an amplifier circuit according to one or more aspects of this disclosure, and a second stage, including a power amplifier according to one or more aspects of this disclosure. The first stage may be located upstream or downstream of the second stage; thus, the amplifier circuit is located upstream or downstream of the power amplifier so as to make the amplifier circuit operate in one of the modes described above.

In an example, the second stage is configured to receive the balanced differential output signal from the first stage. Thus, the first stage defines a stage for preconditioning the input signal to the power amplifier. The audio amplifier may comprises a third stage, including an additional amplifier circuit according to one or more aspects of this disclosure. Thus, the third stage, in particular the additional amplifier circuit, may make the amplifier circuit operate in one of the modes described above.

In an example, the third stage is configured to receive an output signal from the power amplifier, that is, from the second stage.

In particular, the third stage, that is, the additional amplifier circuit, is configured to perform a measurement of the output current and/or voltage from the second stage.

Thus, it is noted that there may be at least three different modes of embodying the audio amplifier. In a first mode, the audio amplifier comprises one (single) amplifier circuit, located upstream of the power amplifier; in this mode, there are a first stage, comprising the amplifier circuit, and a second stage, comprising the power amplifier. In a second mode, the audio amplifier comprises one (single) amplifier circuit, located downstream of the power amplifier; in this mode, there are a second stage, comprising the power amplifier, and a first stage (downstream of the second), comprising the amplifier circuit. In a third mode, the audio amplifier comprises an amplifier circuit located upstream of the power amplifier and comprises an additional amplifier downstream of the power amplifier; in this mode, there are a first stage, comprising the amplifier circuit, a second stage, comprising the power amplifier and located downstream of the first stage, and a third stage, comprising the additional amplifier circuit and located downstream of the second stage.

The amplifier circuit may comprise a processing stage. The processing stage may be located between the amplifier circuit and the power amplifier (that is, between the first stage and the second stage). Thus, the processing stage is configured to process an output signal from the first stage and to feed the processed output signal from the first stage to the second stage (in particular, according to the first and second modes). In an example, the processing stage may be located between the amplifier circuit and the power amplifier and/or between the power amplifier and the additional amplifier circuit (that is, between the first stage and the second stage and/or between the second stage and the third stage). The processing stage may comprise at least an analog-to-digital converter and a digital signal processor. The processing stage may comprise at least a digital-to-analog converter.

### BRIEF DESCRIPTION OF THE DRAWINGS

This and other features will become more apparent from the following description of a preferred embodiment, illustrated by way of non-limiting example in the accompanying drawings, in which:

FIG. 1 illustrates an amplifier circuit according to one or more aspects of this disclosure;

FIGS. 2A-2C illustrates an audio amplifier according to one or more aspects of this disclosure;

FIGS. 3A and 3B illustrate an audio amplifier according to one or more aspects of this disclosure.

### DESCRIPTION OF EXAMPLE EMBODIMENTS

The numeral 1 in the drawings denotes an amplifier circuit. The amplifier circuit 1 comprises an input stage I for receiving as input an audio signal Vᵢₙ, representing the audio signal to be amplified. The input stage I comprises a first input node IN₊ responsible for receiving a first input signal Vᵢₙ₊. The input stage I comprises a second input node IN₋ responsible for receiving a second input signal Vᵢₙ₋. Therefore, the input stage I is an input stage for balancing the input audio signal Vᵢₙ, where the second input signal Vᵢₙ₋ is 180° out of phase with the first input signal Vᵢₙ₊.

The amplifier circuit 1 comprises an isolating stage TI, connected to the input stage I.

The isolating stage TI comprises a transformer T and an additional transformer T′. The transformer T includes a primary winding L₁, having a first terminal m₁ (that is, a first end) and a second terminal m₂, or second end. The first terminal m₁ of the primary winding L₁ is connected to the first input node IN₊ to receive the first input signal Vᵢₙ₊. The additional transformer T′ includes an additional primary winding L₁′, having a first terminal m₁ (that is, a first end) and a second terminal m₂, (that is, a second end). The first terminal m₁ of the additional primary winding L₁′ is connected to the second input node IN₋. The second terminal m₂ of the primary winding L₁ and the second terminal m₂ of the additional primary winding L₁′ are electrically connected in series so that the transformer T and the additional transformer T′ are electrically connected in series between the first input node IN₊ and IN₋.

Preferably, the second terminal m₂ of the primary winding L₁ is connected to the first input node IN₊ through a first input resistor Rᵢₙ₊ and the second terminal m₂ of the additional primary winding L₁′ is connected to the second input node IN₋. In particular, the primary winding L₁ and the additional primary winding L₁′ are connected to each other so as to have discordant polarity. In particular, the magnetic flux generated by the primary winding L₁ is the opposite of the magnetic flux generated by the additional primary winding L₁′.

The transformer T comprises a secondary winding L₂, including a first terminal m₁ (that is, a first end) and a second terminal m₂, (that is, a second end). The secondary winding L₂ comprises a first secondary winding L₂₁ including the first terminal m₁ of the secondary winding L₂, and a second secondary winding L₂₂ including the second terminal m₂ of the secondary winding L₂. The first secondary winding L₂₁ and the second secondary winding L₂₂ are connected to each other by a middle terminal m₃ of the secondary winding L₂. The first secondary winding L₂₁ and the second secondary winding L₂₂ are connected to each other so as to have concordant polarity. The primary winding L₁ and the secondary winding L₂ of the transformer T have concordant polarity, that is, additive polarity.

The additional transformer T′ comprises a secondary winding L₂′, including a first terminal m₁ (that is, a first end) and a second terminal m₂, (that is, a second end). The secondary winding L₂ comprises an additional first secondary winding L₂₁′ including the first terminal m₁ of the additional secondary winding L₂′, and a second secondary winding L₂₂′ including the second terminal m₂ of the additional secondary winding L₂′. The additional first secondary winding L₂₁′ and the additional second secondary winding L₂₂′ are connected to each other by a middle terminal m₃ of the additional secondary winding L₂′. The additional first secondary winding L₂₁′ and the additional second secondary winding L₂₂′ are connected to each other so as to have concordant polarity. The additional primary winding L₁′ and the additional secondary winding L₂′ of the additional transformer T′ have concordant polarity, that is, additive polarity.

The transformer T and the additional transformer T′ define a transformer pair. In an example, the amplifier circuit 1 may comprise a plurality of transformer pairs.

The primary winding L₁ of the transformer T and the additional primary winding L₁′ of the additional transformer T′ are connected in such a way as to have discordant polarity.

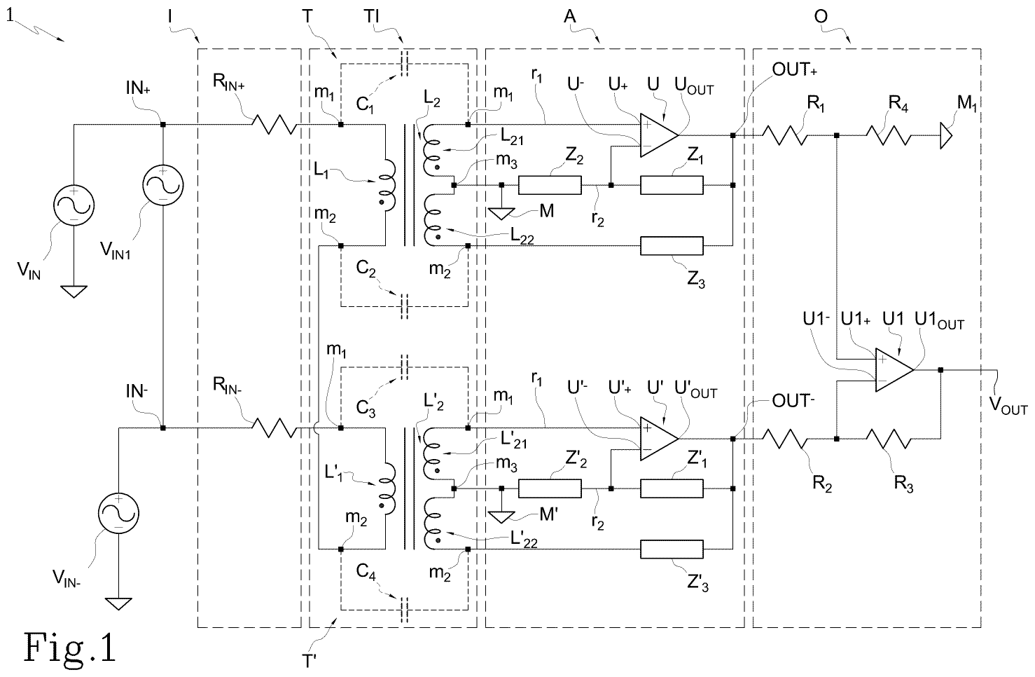

Shown by way of example in FIG. 1 is an amplifier circuit 1 where the primary winding L₁ of the transformer T and the additional primary winding L₁′ of the additional transformer T′ are connected in such a way as to have discordant polarity and the polarity of both of the first primary windings L₂₁ and L₂₁′ is concordant with the polarity of the respective second secondary windings L₂₂, L₂₂′. The polarity of both the primary winding L₁ of the transformer T and the additional primary winding L₁′ of the additional transformer T′ may be inverted with respect to those shown in FIG. 1. The polarities of all the windings may also be inverted with respect to those shown in FIG. 1.

In particular, it is noted that the secondary winding L₂ and the additional secondary winding L₂′ are in separate magnetic circuits.

In the drawings, the stray capacitance produced between the primary winding L₁ and the first secondary winding L₂₁ of the transformer T and between the primary winding L₁ and the second secondary winding L₂₂ of the transformer T are labelled C1 and C2 respectively; the stray capacitance produced between the additional primary winding L₁′ and the additional first secondary winding L₂₁′ of the additional transformer T′ and between the additional primary winding L₁′ and the additional second secondary winding L₂₂′ of the additional transformer T′ are labelled C3 and C4 respectively.

The amplifier circuit 1 comprises an amplifying stage A, connected to the isolating stage TI.

The amplifying stage A comprises a differential amplifier U, including a first input U₊, defining a non-inverting input for the differential amplifier U, a second input U₋, defining an inverting input for the differential amplifier U, and an output Uₒᵤₜ for generating a differential signal at a first output node OUT₊. The first input U₊ is connected to the first terminal m₁ of the secondary winding L₂ by a first connecting branch r₁, and the second input U₋ is connected to the middle terminal m₃ of the secondary winding L₂ by a second connecting branch r₂, and to the output Uₒᵤₜ. The output Uₒᵤₜ is also connected to the second terminal m₂ of the secondary winding L₂.

In particular, the output Uₒᵤₜ is connected to the second input U-through a first impedance Z₁, the second input U₊ is connected to the middle terminal m₃ through a second impedance Z₂ and the second impedance Z₂ is connected to the middle terminal m₃ of the secondary winding L₂ by a ground connection M. The output Uₒᵤₜ is connected to the second terminal m₂ of the secondary winding L₂ through a third impedance Z₃.

The amplifying stage A comprises an additional differential amplifier U′, including a first input U₊′, defining a non-inverting input for the additional differential amplifier U′, a second input U₋′, defining an inverting input for the additional differential amplifier U′, and an output Uₒᵤₜ′ for generating an additional differential signal at a second output node OUT₋.

The first input U₊′ is connected to the first terminal m₁ of the secondary winding L₂ by a first connecting branch r₁, and the second input U₋′ is connected to the middle terminal m₃ of the secondary winding L₂ by a second connecting branch r₂, and to the output Uₒᵤₜ′.

The output Uₒᵤₜ′ is also connected to the second terminal m₂ of the additional secondary winding L₂′.

In particular, the output Uₒᵤₜ of the additional differential amplifier U′ is connected to the second input U₋′ of the additional differential amplifier U′ through an additional first impedance Z₁′, the second input U₊′ of the additional differential amplifier U′ is connected to the middle terminal m₃ through an additional second impedance Z₂′ and the additional second impedance Z₂′ is connected to the middle terminal m₃ of the additional secondary winding L₂′ by an additional ground connection M′. The output Uₒᵤₜ′ of the additional differential amplifier U′ is connected to the second terminal m₂ of the additional secondary winding L₂′ through an additional third impedance Z₃′.

The amplifier circuit 1 comprises an output circuit O, connected to the amplifying stage A.

The output circuit O comprises the first output node OUT₊ to receive the output signal Uₒᵤₜ from the differential amplifier U. The output circuit O comprises the second output node OUT₋ to receive the output signal Uₒᵤₜ′ from the additional differential amplifier U′.

The output circuit O comprises a differential output amplifier U1, including a first input U1₊ defining a non-inverting input for the differential output amplifier U1 and connected to the first output node OUT₊ through a first resistor R1. The differential output amplifier U1 includes a second input U1₋ defining an inverting input for the differential output amplifier U1 and connected to the second output node OUT₋ through a second resistor R2. The differential output amplifier U1 includes an output U1ₒᵤ for generating a differential output signal Vₒᵤₜ. The output U1ₒᵤₜ is connected to the second input U₋ of the differential output amplifier U1 through a third resistor R3. The first output U1₊ is connected to a ground output M1 through a fourth resistor R4.

The numeral 100 in the drawings denotes an audio amplifier.

The audio amplifier 100 comprises an amplifier circuit 1. The audio amplifier 100 comprises a power amplifier 2. In an example, the audio amplifier 100 comprises a first stage S1, including the amplifier circuit 1 and a second stage S2, including the power amplifier 2. The first stage S1 may be located upstream of the second stage S2, so that the amplifier circuit 1 feeds the balanced differential signal Vₒᵤₜ to the audio amplifier 100.

Alternatively, the first stage S1 may be located downstream of the second stage S2, so as to receive an amplified signal Vₐ from the power amplifier 2.

In the case where the first stage S1 is located upstream of the second stage S2, the first stage S1 constitutes a stage for preconditioning the signal (prior to the power amplifying stage). In the case where the first stage S1 is located downstream of the second stage S2, the first stage S1 constitutes a stage for measuring the output signal from the power amplifier 2.

The audio amplifier 100 comprises a processing stage S4, located between the first stage S1 and the second stage S2. Thus, the processing stage S4 is configured to receive the differential output signal Vₒᵤₜ from the first stage S1 and to feed the processed differential output signal Vₒᵤₜ to the second stage S2. Preferably, the processing stage S4 includes an analog-to-digital converter ADC1 and a digital signal processor PD; in addition, the processing stage includes a digital-to-analog converter ADC2.

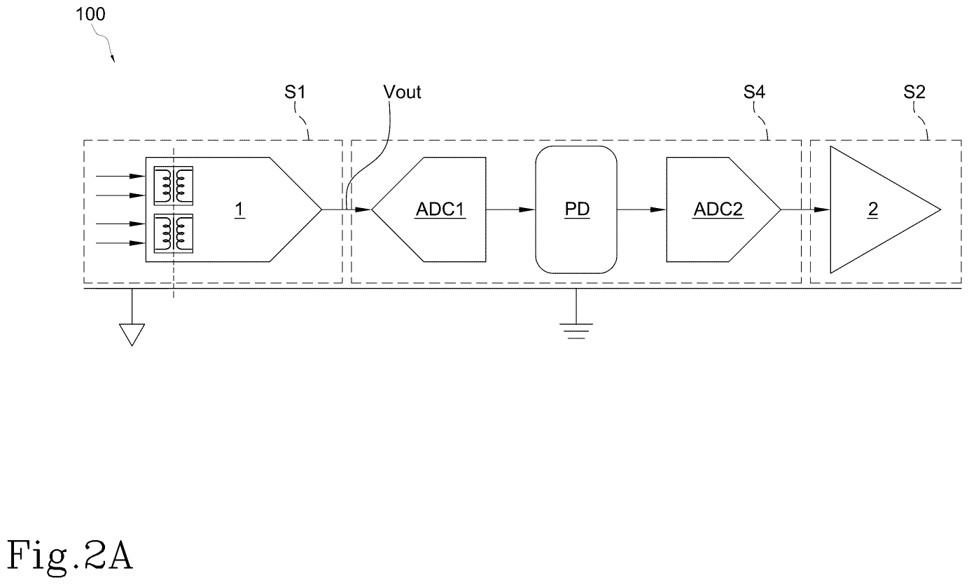

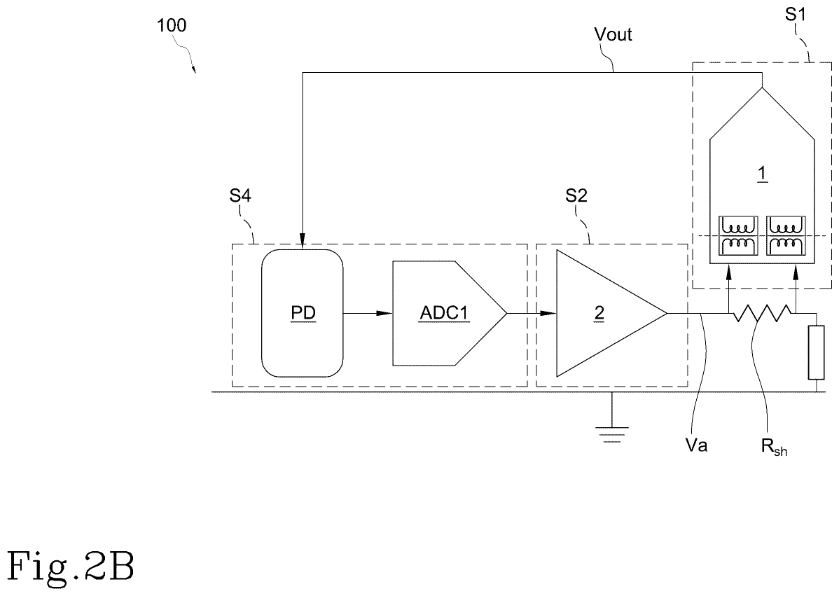

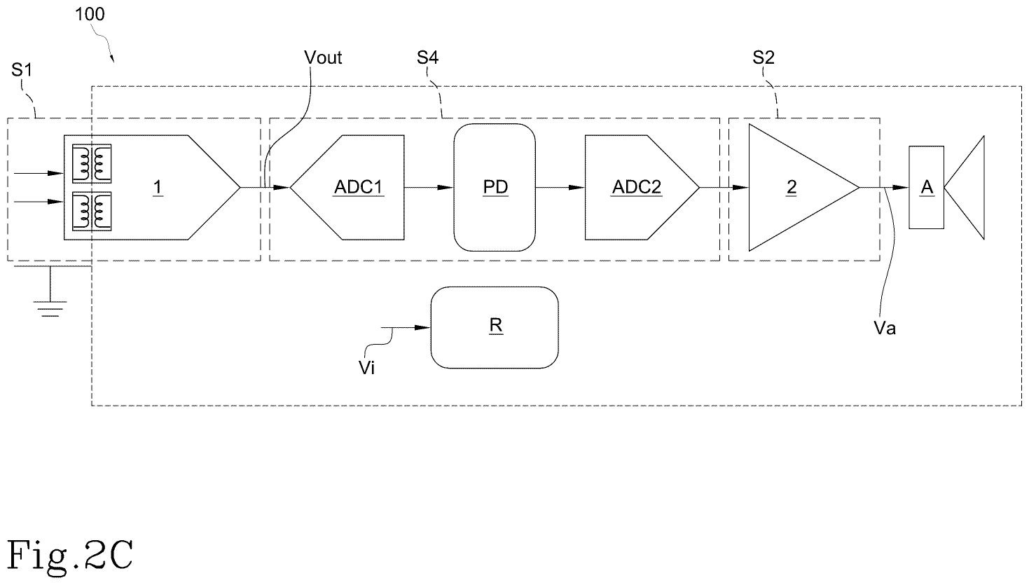

FIG. 2A illustrates, by way of an example, an audio amplifier 100 where the first stage S1 is located upstream of the second stage S2.

FIG. 2B illustrates, by way of an example, an audio amplifier 100 where the first stage S1 is located downstream of the second stage S2. The audio amplifier 100 may include a shunt resistor Rₛₕ, which is part of the measuring stage; the amplifier circuit 1 is connected to the ends of the shunt resistor Rₛₕ to perform a measurement of the current and/or voltage at the ends of the shunt resistor Rₛₕ.

FIG. 2C illustrates, by way of an example, an audio amplifier 100 where the first stage S1 is located upstream of the second stage S2; the audio amplifier 100 is configured to feed an amplified output signal Vₐ from the power amplifier 2 to a loudspeaker A. In the detail, FIG. 2C illustrates an active audio diffuser comprising an audio amplifier 100 configured to receive an input power supply signal Vᵢ from the mains R through an input connector; the amplifier circuit 1 is configured to receive the input power supply signal Vᵢ and to provide a balanced differential output signal Vₒᵤₜ which it feeds to the processing stage S4. The power amplifier 2 is configured to receive the balanced differential output signal Vₒᵤₜ from the processing stage S4 and to provide an amplified output signal Vₐ, which it feeds to the loudspeaker A. Thus, in this case, the amplifier circuit 1, in the first stage S1, constitutes a stage for isolating the input connector from the external mains.

In an example, the audio amplifier 100 comprises an amplifier circuit 1 located in the first stage S1, a power amplifier 2 located in the second stage S2, downstream of the first stage S1, and an additional amplifier circuit located in a third stage, downstream of the second stage S2 and configured to perform a measurement of output current and/or voltage from the power amplifier 2.

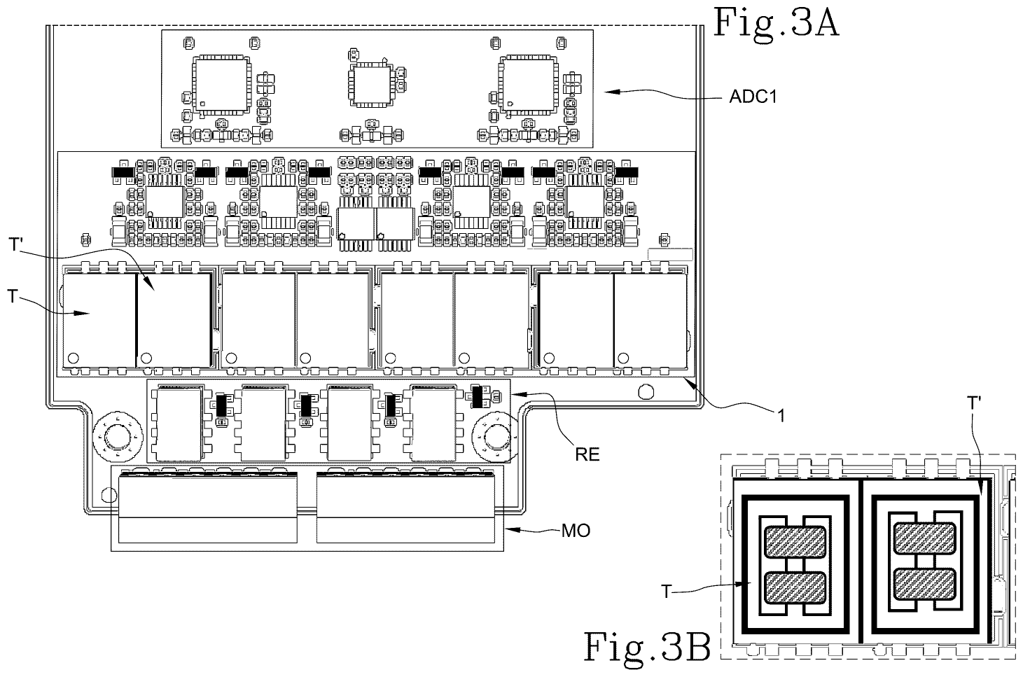

FIG. 3A shows, by way of an example, an electronic card on which there is an amplifier circuit 1, an analog-to-digital converter ADC1, a plurality of relays RE and pins MO. The transformer T and the additional transformer T′ are mounted side by side and oriented in the same way. In particular, the turns of the windings of the transformer T and of the additional transformer T′ are wound along axes which are parallel to each other.

Additionally, the transformer T and the additional transformer T′ are located relative to each other at a distance such that an external magnetic flux generates the same current in the transformer T and in the additional transformer T′. Thus, each transformer T and T′ of the transformer pair has the same mutual orientation (as illustrated, for example, in FIG. 3B).

1. An amplifier circuit for amplifying an audio signal, comprising:
an input stage having a first pin for receiving a first input signal representing the audio signal, and a second pin for receiving a second input signal representing the audio signal and 180° out of phase with respect to the first input signal;
a transformer including a primary winding and a secondary winding, the secondary winding defining a first terminal, a second terminal and a middle terminal;
a differential amplifier, having
a first input, electrically connected to the first terminal of the secondary winding by a first connecting branch;
a second input, electrically connected to the middle terminal of the secondary winding by a second connecting branch; and
an output connected to the second terminal of the secondary winding,
an additional transformer including an additional primary winding and an additional secondary winding, the additional secondary winding defining a first terminal, a second terminal and a middle terminal, wherein the primary winding and the additional primary winding are electrically connected in series between the first pin and the second pin;
an additional differential amplifier, having
a first input, electrically connected to the first terminal of the additional secondary winding by a first connecting branch;
a second input, electrically connected to the middle terminal of the additional secondary winding by a second connecting branch; and
an output connected to the second terminal of the additional secondary winding;
an output circuit for receiving as input the output signals from the differential amplifier and from the additional differential amplifier to generate a differential output signal.

2. The amplifier circuit according to claim 1, wherein the primary winding of the transformer and the additional primary winding of the additional transformer are configured to generate a magnetic flux and an opposite, additional magnetic flux.

3. The amplifier circuit according to claim 1, wherein the transformer and the additional transformer are identical, placed side by side and oriented in the same way, so that an external magnetic flux generates the same current in the transformer and in the additional transformer.

4. The amplifier circuit according to claim 1, wherein, for each of said differential amplifier and additional differential amplifier, the output is connected to the second input by a first impedance.

5. The amplifier circuit according to claim 4, wherein, for each of said differential amplifier and additional differential amplifier:
the second connecting branch (r₂) includes a second impedance, so that the second input is connected to the middle terminal of the respective secondary winding by the second impedance;
the output is connected to the second terminal of the respective secondary winding by a third impedance.

6. The amplifier circuit according to claim 5, comprising an earth connection between the second impedance and the middle terminal.

7. The amplifier circuit according to claim 5, wherein said first impedance, second impedance and third impedance each comprise a resistive component and a capacitive component.

8. The amplifier circuit according to claim 1, wherein the transformer and the additional transformer are identical.

9. The amplifier circuit according to claim 1, wherein the transformer comprises a core and the additional transformer comprises an additional core which is distinct from the core of the transformer.

10. The amplifier circuit according to claim 1, wherein the output circuit comprises a differential output amplifier to generate the differential output signal.

11. An audio amplifier, comprising:
an amplifier circuit according to claim 1;
a power amplifier.

12. The audio amplifier according to claim 11, comprising a first stage including the amplifier circuit and a second stage including the power amplifier, wherein the second stage is configured to receive the differential output signal balanced by the first stage.

13. The audio amplifier according to claim 12, comprising a third stage including an additional amplifier circuit according to claim 1, the third stage being configured to receive an amplified output signal from the second stage.

14. A method for amplifying an audio signal, comprising the following steps:
receiving a first input signal, representing the audio signal, at a first pin of an input stage;
at a second pin of the input stage, receiving a second input signal, representing the audio signal and 180° out of phase with respect to the first input signal;
providing a transformer including a primary winding and a secondary winding, the secondary winding defining a first terminal, a second terminal and a middle terminal;
providing a differential amplifier, having
a first input, electrically connected to the first terminal of the secondary winding by a first connecting branch;
a second input, electrically connected to the middle terminal of the secondary winding by a second connecting branch; and
an output connected to the second terminal of the secondary winding,
providing an additional transformer including an additional primary winding and an additional secondary winding defining a first terminal, a second terminal and a middle terminal, wherein the primary winding and the additional primary winding are electrically connected in series between the first pin and the second pin;
providing an additional differential amplifier, having
a first input, electrically connected to the first terminal of the additional secondary winding by a first connecting branch;
a second input, electrically connected to the middle terminal of the additional secondary winding by a second connecting branch; and
an output connected to the second terminal of the additional secondary winding of the additional transformer;
generating a differential output signal from the output signals from the differential amplifier and from the additional differential amplifier to make the differential output signal available to an output stage.

15. The method according to claim 14, comprising the following steps:
via the primary winding of the transformer, generating a magnetic flux;
via the additional primary winding of the additional transformer, generating a magnetic flux, opposite of the magnetic flux generated by the primary winding.

16. The method according to claim 14, wherein the transformer and the additional transformer are identical, placed side by side and oriented in the same way, so that an external magnetic flux generates the same current in the transformer and in the additional transformer.

17. The method according to claim 16, wherein, for each of said differential amplifier and additional differential amplifier:
the output is connected to the second input of the respective differential amplifier by a first impedance;
the second connecting branch includes a second impedance, so that the second input is connected to the middle terminal of the respective secondary winding by the second impedance and the second impedance is connected to the middle terminal by an earth connection;
the output is connected to the second end of the respective secondary winding by a third impedance.

18. The method according to claim 14, comprising a step of providing a differential output amplifier having an output circuit to generate the differential output signal.

19. The audio amplifier according to claim 12, comprising a pre-processing stage, located between the first stage and the second stage and configured for receiving the differential output signal from the first stage and for feeding the processed differential output signal to the second stage, the pre-processing stage including an analog-to-digital converter, a digital signal processor and a digital-to-analog converter.

20. A loudspeaker comprising an audio amplifier according to claim 14, wherein:
the audio amplifier is configured for receiving an input power signal from a network through an input connector,
the amplifier circuit is configured for outputting a balanced differential signal and for feeding the balanced differential output signal to the pre-processing stage, and
the power amplifier is configured for receiving the pre-processed balanced differential signal from the processing stage and for feeding an amplified signal to the loudspeaker.
